(19) United States
(12) Patent Application Publication
(10) Pub. No.: US 2006/0205218 A1
(43) Pub. Date: Sep. 14, 2006

(54) Compositions and methods for chemical mechanical polishing thin films and dielectric materials

(76) Inventor: Brian L. Mueller, Middletown, DE (US)

Correspondence Address: ROHM AND HAAS ELECTRONIC MATERIALS;CMP HOLDINGS, INC., 451 BELLEVUE ROAD, NEWARK, DE, 19713, US

(21) Appl. No.: 11/354,403

(22) Filed: Feb. 14, 2006

Related U.S. Application Data
(60) Provisional application No. 60/659,823, filed on Mar. 9, 2005.

(51) Int. Cl. C09K 3/14; C09K 13/00; B24D 3/02; B44C 1/22; H01L 21/461

(52) U.S. Cl. 438/692; 51/307; 51/308; 51/304; 252/79.1; 216/88

(57) ABSTRACT

The present invention provides an aqueous composition useful for polishing conducting, semi-conducting and dielectric materials on a semiconductor wafer comprising by weight percent 0.01 to 5 zwitterionic compound, 0.01 to 5 cationic compound, 0.5 to 10 abrasive, 0 to 5 inorganic acids and salts thereof, and balance water, wherein the abrasive is filmed silica that has only been exposed to an acidic pH. The composition and method provide unexpected selectivity for removing conductive and semi-conductive layers relative to dielectric layers.

This application claims the benefit of U.S. Provisional Patent Application Ser. No. 60/659,823 filed Mar. 9, 2005.

### BACKGROUND OF THE INVENTION

The invention relates to chemical mechanical planarization (CMP) of semiconductor wafer materials and, more particularly, to CMP compositions and methods useful for polishing, for example, silicon nitride and various interconnect layers, and thin-films used in semiconductor integrated circuit manufacturing with high selectivity to interlayer dielectric materials.

A semiconductor wafer typically includes a substrate, such as a silicon or gallium arsenide wafer, on which a plurality of electronic devices have been formed. Electronic devices such as transistors and capacitors are chemically and physically connected to the substrate by patterning regions in the substrate and layers on the substrate. The devices and layers are separated by interlevel dielectrics (ILDs), comprised primarily of some form of silicon oxide (SiO₂) material. The devices are interconnected through the use of well known multilevel interconnects to form functional circuits. Typical multilevel interconnects are comprised of stacked conducting and semi-conducting thin-films consisting of one or more of the following materials: silicon, polysilicon, doped polysilicon (Poly-Si), amorphous silicon, silicon nitride or various combinations thereof. In addition, devices are isolated from one another, often through the use of trenches filled with an insulating material, such as, boron and phosphorous doped silicon glass (BPSG) or tetraethylorthosilicate (TEOS).

As discussed, the semiconductor devices of the semiconductor structure are formed by alternately depositing and patterning layers of conducting, semi-conducting and insulating material on the surface of the semiconductor structure. Frequently, in preparation for the deposition of successive layers, the surface of the semiconductor structure is required to be rendered smooth and flat. Thus, in order to prepare the surface of the semiconductor structure for a material deposition operation, a planarization process is required to be conducted on the surface of the semiconductor structure. Planarization is typically implemented by growing or depositing an interlevel dielectric layer of insulating material such as an oxide or nitride on the semiconductor structure, to fill in rough or discontinuous areas. Interlevel dielectric layers are deposited as a conformal film, causing it to have a non-planar surface characterized by vertically raised protruding features of a greater height extending upward above the arrays and by open troughs of a lower height in other areas. The planarization process is used to reduce the height of the vertically protruding features down to a target height that is typically a predefined distance above the level of the tops of the arrays where, ideally, a planarized surface will be formed.

Currently, CMP is the foremost technique to achieve the desired flatness or planarization. CMP enhances the removal of surface material, mechanically abrading the surface while a chemical composition (“slurry”) selectively attacks the surface. Current generation devices require that the surface be planarized either to a precise thickness or planarized and polished through to expose hetero-materials. The chemical composition must be able to polish the exposed hetero-materials either at a determined rate or have very low polish rates. In the case where the rate is low, the desired effect is for the exposed film to function as a “stop” layer to improve planarity and CMP process margins. Steckenrider et al. discloses, in U.S. Pat. No. 6,533,832, an aqueous chemical mechanical polishing slurry useful for polishing the polysilicon layer of a semiconductor wafer comprising an aqueous solution of at least one abrasive, and at least one alcoholamine. The slurry has a pH of 9.0 to 10.5 and it includes an optional buffering agent.

Although current slurry compositions are suitable for limited purposes, they tend to exhibit unacceptable polishing rates and corresponding selectivity levels to semiconducting and insulator materials used in wafer manufacture. In addition, known polishing slurries tend to produce poor film removal traits for the underlying films or produce deleterious film-corrosion that leads to poor manufacturing yields.

Hence, what is needed is a composition and method for chemical-mechanical polishing of semiconducting, conducting and dielectric layers having improved selectivity to the insulator media surrounding the trenches or interconnects. A further need remains for a single slurry that is capable of providing both high and uniform removal rates of the semiconducting and conducting layers, with high selectivities to the exposed insulator films.

### STATEMENT OF THE INVENTION

In a first aspect, the present invention provides an aqueous composition useful for polishing conducting, semi-conducting and dielectric materials on a semiconductor wafer comprising by weight percent 0.01 to 5 zwitterionic compound, 0.01 to 5 cationic compound, 0.5 to 10 abrasive, 0 to 5 inorganic acids and salts thereof, and balance water, wherein the abrasive is fumed silica that has only been exposed to an acidic pH.

In another aspect, the present invention provides an aqueous composition useful for polishing silicon nitride and a dielectric layer on a semiconductor wafer comprising by weight percent 0.01 to 5 N,N,N-trimethylammonioacetate, 0.01 to 5 cationic compound, 0.5 to 10 abrasive, 0 to 5 inorganic acids and salts thereof, and balance water, wherein the aqueous composition has a pH of 2 to 9 and wherein the abrasive is fumed silica that has a surface area of greater than 90 m²/g and has only been exposed to an acidic pH.

In another aspect, the present invention provides a method for polishing conducting, semi-conducting and dielectric materials on a semiconductor wafer comprising: contacting the conducting, semi-conducting and dielectric materials on the wafer with a polishing composition, the polishing composition comprising by weight percent 0.01 to 5 zwitterionic compound, 0.01 to 5 cationic compound, 0.5 to 10 abrasive, 0 to 5 inorganic acids and salts thereof, and balance water, wherein the abrasive is fumed silica that has only been exposed to an acidic pH.

### DETAILED DESCRIPTION OF THE INVENTION

The composition and method provide unexpected selectivity for removing conductive and semi-conductive layers with high selectivity to ILD materials. The composition advantageously relies upon an acidic abrasive to selectively polish the conductive and semi-conductive layers with high selectivity to ILD materials. In particular, the composition comprises an acidic pH-only processed fumed silica to selectively polish the conductive and semi-conductive layers and dielectric materials, at the pH of the application.

As defined herein, the term “alkyl” (or alkyl- or alk-) refers to a substituted or unsubstituted, straight, branched or cyclic hydrocarbon chain that preferably contains from 1 to 20 carbon atoms. Alkyl groups include, for example, methyl, ethyl, propyl, isopropyl, cyclopropyl, butyl, iso-butyl, tert-butyl, sec-butyl, cyclobutyl, pentyl, cyclopentyl, hexyl and cyclohexyl.

The term “aryl” refers to any substituted or unsubstituted aromatic carbocyclic group that preferably contains from 6 to 20 carbon atoms. An aryl group can be monocyclic or polycyclic. Aryl groups include, for example, phenyl, naphthyl, biphenyl, benzyl, tolyl, xylyl, phenylethyl, benzoate, alkylbenzoate, aniline, and N-alkylanilino.

The term “zwitterionic compound” means a compound containing cationic and anionic substituents in equal proportions joined by a physical bridge, for example, a CH₂ group, so that the compound is net neutral overall. The zwitterionic compounds of the present invention include the following structure: 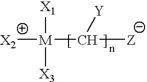
wherein n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

Preferred zwitterionic compounds include, for example, betaines. A preferred betaine of the present invention is N,N,N-trimethylammonioacetate, represented by the following structure:

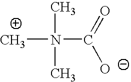

The composition advantageously contains 0.01 to 5 weight percent zwitterionic compound to selectively remove the silica relative to the silicon nitride. Advantageously, the composition contains 0.05 to 1.5 weight percent zwitterionic compound. The zwitterionic compound of the present invention may advantageously promote planarization and may suppress nitride removal.

In addition to the zwitterionic compound, the composition of the present invention advantageously comprises 0.01 to 5 weight percent cationic compound. Preferably, the composition optionally comprises 0.05 to 1.5 weight percent cationic compound. The cationic compound of the present invention may advantageously promote planarization, regulate wafer-clearing time and serve to suppress oxide removal. Preferred cationic compounds include, alkyl amines, aryl amines, quaternary ammonium compounds and alcohol amines. Exemplary cationic compounds include, methylamine, ethylamine, dimethylamine, diethylamine, trimethylamine, triethylamine, aniline, tetramethylammoniumhydroxide, tetraethylammoniumhydroxide, ethanolamine and propanolamine. Preferred cationic compounds are alcohol amines.

Advantageously, the solution contains, by weight percent, 0.5 to 10 fumed silica abrasive. For purposes of this specification, all compositions are expressed in weight percent unless expressly noted otherwise. Preferably, the solution contains, by weight percent, 1 to 6 fumed silica abrasive. Most preferably, the solution contains, by weight percent, 2 to 4 fumed silica abrasive.

As used herein, an “acidic pH only processed abrasive,” “acidic pH only processed fumed silica,” “acidic abrasive,” and “acidic fumed silica,” are defined as an abrasive that has only been processed at an acidic pH. In other words, the abrasive was not dispersed or diluted in a basic solution at any point.

In a preferred embodiment, the acidic fumed silica of the present invention is fabricated by initially charging a mixer with a predetermined volume of de-ionized water. Preferably, the mixer utilized is a high shear mixer, for example, a Myers Mixer manufactured by Meyers Engineering, Inc. of Bell, Calif. Fumed silica, for example, Aerosil 130 is commercially available from Degussa, of Parsippany, N.J. Thereafter, a predetermined amount of acid is added to the water based upon the desired pH. After the addition of acid to the water, the mixer operates to mix the acid and water to form an acidic water solution. The acid may be a mineral or organic acid such as hydrochloric acid, sulfuric acid, nitric acid, phosphoric acid, acetic acid or maleic acid. Preferably, the acid is hydrochloric acid.

Advantageously, the quantity of acid added to the water is an amount, by weight percent, between 0.0010 and 0.50 of fumed silica that will be added to the water. Preferably, the quantity of acid added to the water is an amount, by weight percent, between 0.0015 and 0.15 of fumed silica that will be added to the water.

The initial quantity of water chosen is based on the amount of fumed silica to be added, and the desired final concentration of fumed silica in the aqueous dispersion. For example, if the desired final concentration of the aqueous dispersion of fumed silica is by weight percent 35 fumed silica, then the initial quantity of water is that quantity or concentration that will result in a greater than 35 weight percent fumed silica in the mixer. In the present invention, the dispersion will have a fumed silica concentration about 5 weight percent greater than the desired final concentration of fumed silica in the aqueous dispersion of fumed silica. Thereafter, the aqueous dispersion in the mixer will be diluted by the addition of an additional amount of water to achieve the desired final concentration of fumed silica.

Next, fumed silica is dispersed in the water-acid solution in the mixer to a predetermined concentration. Advantageously, the temperature of the solution is maintained at less than 60° C., preferably, less than 35° C. The fumed silica may be added by mixing the fumed silica into the water-acid mixture while the mixer is operating, or by adding the fumed silica to the water-acid mixture and then operating the mixer. The fumed silica may also be added incrementally, in a series of steps, with the mixer operating between each step. After the concentration of fumed silica in the aqueous dispersion has been raised to a point above the desired final concentration of fumed silica, the mixer is allowed to operate until the dispersion in the mixer reaches a desired viscosity. The high shear mixing breaks down the agglomerated structure of the dry fumed silica causing the viscosity to drop. Hence, the high shear mixing is maintained throughout the process to cause deagglomeration. If the mixer stops, the dispersion may gel and lock up the mixer and result in unwanted, larger particles in the dispersion. As discussed, the dispersion in the mixer, before dilution, will have a fumed silica concentration about 5 percent greater than the desired final concentration of fumed silica.

Advantageously, the aqueous dispersion contains, by weight percent, at least 35 fumed silica. Preferably, the aqueous dispersion contains, by weight percent, between 40 to 65 fumed silica. In addition, the fumed silica advantageously has a surface area greater than 90 m²/g. Preferably, the fumed silica advantageously has a surface area greater than 130 m²/g.

Next, the dispersion is rapidly diluted by the addition of de-ionized water. The additional water is then mixed into the aqueous dispersion in the mixer. The amount of water added is an amount sufficient to lower the concentration of fumed silica in the aqueous dispersion to the desired final concentration. Note, the pH of the solution during dilution is maintained, at all times, between 1 to 7. Preferably, the pH of the solution is 1.5 to 5.5.

Thereafter, the aqueous dispersion of fumed silica may be centrifuged or decanted, as desired. In addition, the aqueous dispersion of fumed silica may be passed through a filter to remove grit and any agglomerated fumed silica particles. In particular, any unwanted particles having a diameter greater than 1 micrometer is filtered. Thereafter, the filtered fumed silica may be packaged, as desired, for future use.

Hence, the fumed silica of the present invention is dispersed and diluted, at all times, at a pH of 1 to 7. Preferably, the pH is 1.5 to 5.5. In addition, the fumed silica advantageously has a surface area greater than 90 m²/g. Preferably, the fumed silica advantageously has a surface area greater than 130 m²/g.

The compounds provide efficacy over a broad pH range in solutions containing a balance of water. This solution's useful pH range extends from at least 2 to 9. In addition, the solution advantageously relies upon a balance of deionized water to limit incidental impurities. The pH of the polishing fluid of this invention is preferably from 3 to 8, more preferably a pH of 5.5 to 8.0. The acids used to adjust the pH of the composition of this invention are, for example, nitric acid, sulfuric acid, hydrochloric acid, phosphoric acid and the like. Exemplary bases used to adjust the pH of the composition of this invention are, for example, ammonium hydroxide and potassium hydroxide.

Optionally, the composition advantageously contains 0 to 5 weight percent inorganic acids and salts thereof for enhanced colloidal stability. Preferably, the composition optionally contains 0.01 to 1 weight percent inorganic acids and salts thereof. Example inorganic additives include sulfuric acid, phosphoric acid, nitric acid, HF acid, ammonium fluoride, ammonium salts, potassium salts, sodium salts or other cationic salts of sulfates, phosphates and fluorides.

Accordingly, the composition and method provide unexpected selectivity for removing conductive and semi-conductive layers relative to dielectric materials. The composition advantageously relies upon an acidic abrasive to selectively polish the conductive and semi-conductive layers relative to dielectric materials. In particular, the composition comprises an acidic pH-only processed fumed silica to selectively polish the conductive and semi-conductive layers relative to dielectric materials, at the pH of the application.

### EXAMPLES

In the Examples, the numeral represents the example of the invention and the letter represents a comparative example. All example solutions contained, by weight percent, 0.25 tetramethylammonium hydroxide (TMAN). The grade of the Klebosol® was 1498-50.

### Example 1

This experiment measured the selectivity of the present composition for certain conducting, semi-conducting and dielectric materials. In particular, the effects of an acidic pH-only processed fumed silica on selectivity of silicon and silicon nitride relative to PTEOS and BPSG were tested. A Strasbaugh 6EC polishing machine using an IC1010™ polyurethane polishing pad (Rohm and Haas Electronic Materials CMP Inc.) under downforce conditions of 4 psi (27.58 kPa) and a polishing solution flow rate of 150 cc/min, a platen speed of 93 RPM and a carrier speed of 87 RPM planarized the samples. The polishing solutions had a pH of 8 adjusted with nitric acid or ammonium hydroxide. All solutions contained balance deionized water.

TABLE 1

| | Silica | | Silicon | | | | |
|---|---|---|---|---|---|---|---|
| | Concentration | Silicon RR | nitride RR | PTEOS RR | BPSG RR | Selectivity | Selectivity |
| Test | (Wt. %) | (Å/min) | (Å/min) | (Å/min) | (Å/min) | (SiN/PTEOS) | (SiN/BPSG) |
| A | 15 Klebesol | 6124 | 756 | 1175 | 2057 | 0.64 | 0.36 |
| 1 | 10 fumed | 4360 | 656 | 125 | 423 | 5.25 | 1.55 |

As illustrated in Table 1 above, the addition of the fumed silica improved the selectivity of the composition. In particular, the addition of the low-pH treated fumed silica improved the selectivity of the composition of Test 1 for the silicon nitride relative to the PTEOS from 0.64 (Test A) to 5.25. Also, the addition of the low-pH treated fumed silica improved the selectivity of the composition of Test 1 for the silicon nitride relative to the BPSG from 0.36 (Test A) to 1.55.

### Example 2

This experiment measured the effect of the various concentrations of the components of the present composition on the selectivity for certain conducting, semi-conducting and dielectric materials. In particular, the effects of an acidic pH-only processed fumed silica, as well as various concentrations of an alcohol amine and a zwitterionic compound, on selectivity of silicon nitride relative to BPSG were tested. An Applied Materials Mirra® polishing machine using an WP3000™ polyurethane polishing pad (Rohm and Haas Electronic Materials CMP Inc.) under downforce conditions of 4 psi (27.58 kPa) and a polishing solution flow rate of 150 cc/min, a platen speed of 93 RPM and a carrier speed of 87 RPM planarized the samples. The polishing solutions had a pH of 8 adjusted with nitric acid or ammonium hydroxide. Some test solutions contained an optional inorganic additive. All solutions contained balance deionized water.

TABLE 2

| | | Phos- | Amino | | SiN | | Selec- |
|---|---|---|---|---|---|---|---|
| | Silica | phoric | Methyl | | RR | BPSG | tivity |
| | Conc. | Acid | Propanol | Betaine | (Å/ | RR | (SiN/ |
| Test | (Wt. %) | (Wt. %) | (Wt. %) | (Wt. %) | min) | (Å/min) | BPSG) |
| 2 | 6 | 0.36 | 0.75 | 0.0 | 469 | 100 | 4.69 |
| 3 | 4 | 0.36 | 0.75 | 0.0 | 352 | 56 | 6.29 |
| 4 | 6 | 0.35 | 0.75 | 0.10 | 414 | 72 | 5.75 |
| 5 | 6 | 0.35 | 0.50 | 0.75 | 483 | 129 | 3.74 |
| 6 | 6 | 0.35 | 0.50 | 0.75 | 466 | 65 | 7.17 |
| 7 | 4 | 0.0 | 1.00 | 0.0 | 389 | 50 | 7.78 |
| 8 | 4 | 0.20 | 0.50 | 0.75 | 341 | 37 | 9.21 |
| 9 | 4 | 0.38 | 0.75 | 0.10 | 350 | 74 | 4.73 |

As illustrated in Table 2 above, the present composition provided a selectivity of at least 3.74 (Test 5). Decreasing the fumed silica concentration seems to increase the selectivity (Tests 2, 3). The addition of the betaine appears to improve selectivity. For example, The selectivity was improved from 4.69 in Test 2 to 5.75 in Test 4 with the addition of 0.10 weight percent betaine.

Accordingly, the composition and method provide unexpected selectivity for removing conductive and semi-conductive layers relative to dielectric materials. The composition advantageously relies upon an acidic abrasive to selectively polish the conductive and semi-conductive layers relative to dielectric materials. In particular, the composition comprises an acidic pH-only processed fumed silica to selectively polish the conductive and semi-conductive layers relative to dielectric materials, at the pH of the application.

1. An aqueous composition useful for polishing conducting, semi-conducting and dielectric materials on a semiconductor wafer comprising by weight percent 0.01 to 5 zwitterionic compound, 0.01 to 5 cationic compound, 0.5 to 10 abrasive, 0 to 5 inorganic acids and salts thereof, and balance water, wherein the abrasive is fumed silica that has only been exposed to an acidic pH.

2. The composition of claim 1 wherein the abrasive has a surface area of greater than 90 m²/g.

3. The composition of claim 1 wherein the zwitterionic compound has the following structure: 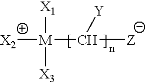
in which n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

4. The composition of claim 1 wherein the zwitterionic compound has the following structure:

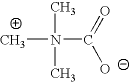

5. The composition of claim 1 wherein the cationic compound is selected from the group comprising: alkyl amines, aryl amines, quaternary ammonium compounds and alcohol amines.

6. The composition of claim 1 wherein the aqueous composition has a pH of 2 to 9.

7. An aqueous composition useful for polishing silicon nitride and a dielectric layer on a semiconductor wafer comprising by weight percent 0.01 to 5 N,N,N-trimethylammonioacetate, 0.01 to 5 cationic compound, 0.5 to 10 abrasive, 0 to 5 inorganic acids and salts thereof, and balance water, wherein the aqueous composition has a pH of 2 to 9 and wherein the abrasive is fumed silica that has a surface area of greater than 90 m²/g and has only been exposed to an acidic pH.

8. A method for polishing conducting, semi-conducting and dielectric materials on a semiconductor wafer comprising:
contacting the conducting, semi-conducting and dielectric materials on the wafer with a polishing composition, the polishing composition comprising by weight percent 0.01 to 5 zwitterionic compound, 0.01 to 5 cationic compound, 0.5 to 10 abrasive, 0 to 5 inorganic acids and salts thereof, and balance water, wherein the abrasive is fumed silica that has only been exposed to an acidic pH.

9. The method of claim 8 wherein the abrasive has a surface area of greater than 90 m²/g.

10. The method of claim 8 wherein the zwitterionic compound has the following structure: 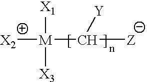
in which n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.
